(19) United States
(12) Patent Application Publication
(10) Pub. No.: US 2021/0190870 A1
(43) Pub. Date: Jun. 24, 2021

(54) COMBINATION DETERMINATION APPARATUS, COMBINATION DETERMINATION METHOD, AND PROGRAM

(71) Applicant: HONDA MOTOR CO., LTD., Tokyo (JP)

(72) Inventor: Naoki Maruno, Wako-shi (JP)

(21) Appl. No.: 17/128,357

(22) Filed: Dec. 21, 2020

(30) Foreign Application Priority Data
Dec. 23, 2019 (JP) 2019-231881

(51) Int. Cl. G01R 31/388

(52) U.S. Cl. CPC G01R 31/388; H02J 7/0047

(57) ABSTRACT

A combination determination apparatus includes: a selection part that selects, from a plurality of secondary batteries having a use history, a reference battery when part or all of the plurality of secondary batteries are combined to be a secondary use battery, based on a state of each of the plurality of secondary batteries; and a determination part that determines an availability of each of secondary batteries other than the reference battery among the plurality of secondary batteries as a combination battery that are combined with the reference battery to be the secondary use battery, based on a state of each of the secondary batteries other than the reference battery.

### CROSS-REFERENCE TO RELATED APPLICATION

Priority is claimed on Japanese Patent Application No. 2019-231881, filed on Dec. 23, 2019, the contents of which are incorporated herein by reference.

### BACKGROUND

### Field of the Invention

The present invention relates to a combination determination apparatus, a combination determination method, and a program.

### Background

In recent years, secondary use of a secondary battery (battery) for on-vehicle use mounted on an electric vehicle has progressed. The secondary use of the secondary battery includes reuse as an on-vehicle secondary battery mounted on another vehicle and use in other applications, for example, use in an electric power storage system. In the related art, a battery secondary use management system has been disclosed which determines a secondary use destination of a battery in use in advance before the end of use on the basis of an expected end-of-use timing (for example, refer to PCT International Publication No. WO2015/012144).

### SUMMARY

It is possible for a user aiming at secondary use of a secondary battery to understand the performance of the secondary battery after the end of use to some extent, but it is difficult for the user to understand the performance when combining such secondary batteries. Therefore, in secondary use in which a plurality of secondary batteries are combined, it is difficult to select a secondary battery to be used.

Aspects of the present invention provide a combination determination apparatus, a combination determination method, and a program capable of suitably selecting a secondary battery used for secondary use.

A first aspect of the present invention is a combination determination apparatus including: a selection part that selects, from a plurality of secondary batteries having a use history, a reference battery when part or all of the plurality of secondary batteries are combined to be a secondary use battery, based on a state of each of the plurality of secondary batteries; and a determination part that determines an availability of each of secondary batteries other than the reference battery among the plurality of secondary batteries as a combination battery that are combined with the reference battery to be the secondary use battery, based on a state of each of the secondary batteries other than the reference battery.

A second aspect of the present invention is the combination determination apparatus according to the first aspect described above, wherein the determination part may determine the availability of each of the secondary batteries other than the reference battery among the plurality of secondary batteries, based on a use environment of the secondary use battery.

A third aspect of the present invention is the combination determination apparatus according to the first or second aspect described above, wherein the determination part may determine the availability of each of the secondary batteries other than the reference battery among the plurality of secondary batteries, based on a total cost of the secondary use battery.

A fourth aspect of the present invention is the combination determination apparatus according to any of the first to third aspects described above, wherein the selection part may select the reference battery based on a variation in a condition of the secondary battery.

A fifth aspect of the present invention is the combination determination apparatus according to any of the first to fourth aspects described above which may further include: a communication part that communicates with a terminal device; an acquisition part that acquires a state of a secondary battery that corresponds to identification information of the secondary battery that is transmitted by the terminal device; and a transmission control part that causes the communication part to transmit a determination result by the determination part, wherein the determination part may specify a secondary battery of which an availability is determined based on the identification information of the secondary battery that is transmitted by the terminal device, and the transmission control part may cause the communication part to transmit the determination result by the determination part to the terminal device that has transmitted the identification information.

A sixth aspect of the present invention is the combination determination apparatus according to any of the first to fourth aspects described above which may further include: a generation part that generates a combination pattern of the secondary batteries to be the secondary use battery based on a selection result of the selection part and a determination result of the determination part; and a provision part that provides a generation result of the generation part, wherein the generation part may generate a plurality of combinations of the secondary batteries to be the secondary use battery, and the provision part may provide a plurality of combinations of the secondary batteries.

A seventh aspect of the present invention is a combination determination method by a computer, including: selecting, from a plurality of secondary batteries having a use history, a reference battery when part or all of the plurality of secondary batteries are combined to be a secondary use battery, based on a state of each of the plurality of secondary batteries; and determining an availability of each of secondary batteries other than the reference battery among the plurality of secondary batteries as a combination battery that are combined with the reference battery to be the secondary use battery, based on a state of each of the secondary batteries other than the reference battery.

An eighth aspect of the present invention is a computer-readable non-transitory recording medium that includes a program causing a computer to: select, from a plurality of secondary batteries having a use history, a reference battery when part or all of the plurality of secondary batteries are combined to be a secondary use battery, based on a state of each of the plurality of secondary batteries; and determine an availability of each of secondary batteries other than the reference battery among the plurality of secondary batteries as a combination battery that are combined with the reference battery to be the secondary use battery, based on a state of each of the secondary batteries other than the reference battery.

According to the first to eighth aspects described above, it is possible to suitably select a secondary battery used for secondary use.

According to the second and third aspects described above, it is possible to determine the availability of each of the secondary batteries other than the reference battery in accordance with a user's request.

According to the fourth aspect described above, it is possible to make it easier to determine the availability of each of the secondary batteries other than the reference battery.

According to the fifth aspect described above, it is possible to provide combination information to a user requiring the combination information.

According to the sixth aspect described above, it is possible to provide combination information to a user having less information of the secondary battery.

### BRIEF DESCRIPTION OF THE DRAWINGS

FIG. 1 is a view showing an example of a combination determination system according to a first embodiment.

FIG. 2 is a view showing an example of a configuration of a vehicle.

FIG. 3 is a view showing an example of a configuration of a terminal device.

FIG. 4 is a view showing an example of a configuration of a combination determination apparatus.

FIG. 5 is a view showing an example of a battery database.

FIG. 6 is a view showing an example of an image displayed on a terminal device in which a combination information request application has been activated.

FIG. 7 is a view showing an example of an image displayed on the terminal device of which an agreement button has been operated.

FIG. 8 is a view showing an example of an image displayed on the terminal device after setting a total cost and a use environment of a secondary use battery.

FIG. 9 is a view showing an example of an image displayed on the terminal device after a two-dimensional code is read by an image capture part.

FIG. 10 is a view showing an example of an image displayed on the terminal device that receives combination information.

FIG. 11 is a view showing another example of an image displayed on the terminal device that receives combination information.

FIG. 12 is a flowchart showing an example of a process in the combination determination apparatus.

FIG. 13 is a flowchart showing another example of a process in the combination determination apparatus.

FIG. 14 is a view showing an example of a configuration of a combination determination apparatus according to a second embodiment.

FIG. 15 is a view showing an example of an image displayed on the terminal device that receives combination information.

### DESCRIPTION OF EMBODIMENTS

Hereinafter, embodiments of a combination determination apparatus, a combination determination method, and a program of the present invention will be described with reference to the drawings. In the following description, it is assumed that a vehicle 10 is an electric vehicle. However, it is only necessary for the vehicle 10 to be a vehicle that is externally chargeable and a vehicle on which a secondary battery that supplies electric power for traveling is mounted. The vehicle 10 may be a hybrid vehicle or a fuel-cell vehicle.

### First Embodiment

A first embodiment of a combination determination apparatus is described.

[Overall Configuration]

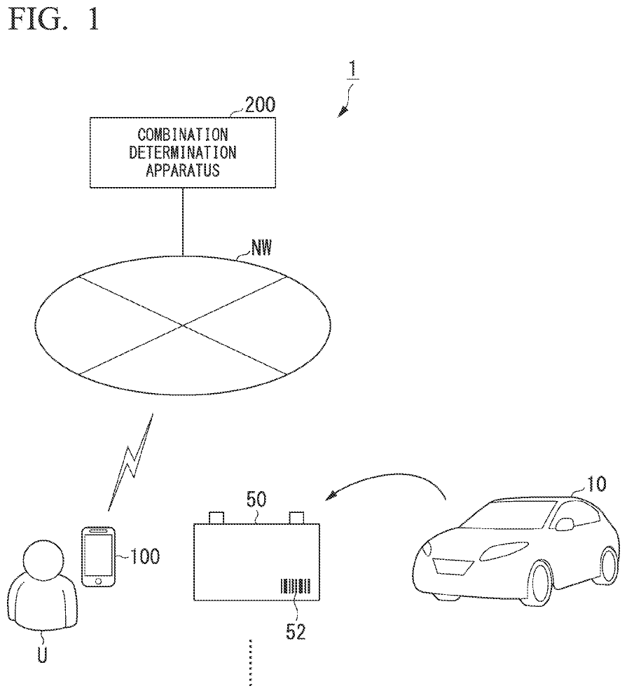

FIG. 1 is a view showing an example of a combination determination system 1 according to the first embodiment. The combination determination system 1 is a system that determines, when a plurality of used batteries are combined and reused, an availability of a combination of the used battery. The used battery is, for example, a battery which has a use history mounted on the vehicle 10 and becomes a used one. The combination determination system 1 provides combination information regarding a combination of the used batteries by the combination determination apparatus 200 to the terminal device 100 in response to a request of the terminal device 100.

As shown in FIG. 1, the combination determination apparatus 200 communicates with the terminal device 100 via a network NW. The network NW includes, for example, the Internet, a WAN (Wide Area Network), a LAN (Local Area Network), a provider device, a radio base station, and the like. The terminal device 100 is, for example, a portable terminal used by a user manufacturing a battery (hereinafter, referred to as a “secondary use battery”) obtained by combining part or all of the used batteries.

The combination determination apparatus 200 stores battery information of a plurality of used batteries 50 that become a used one and that are removed from the vehicle 10. The battery information is information indicating a battery state and is, for example, information of a battery state such as a “normal temperature capacity”, a “low temperature capacity”, and a “self-discharge performance” of the used battery 50. The battery information may be, for example, battery information transmitted by a vehicle or information provided from a vendor or the like that has removed the used battery 50 from the vehicle 10.

The terminal device 100 sequentially reads a two-dimensional code 52 attached to each of the plurality of used batteries 50, for example, by an operation of a user U and acquires a plurality of code information. The terminal device 100 transmits the plurality of acquired code information to the combination determination apparatus 200. The combination determination apparatus 200 selects a reference battery from the plurality of used batteries 50 using the plurality of code information and the like. The reference battery is a used battery that becomes, when manufacturing the secondary use battery, a reference in identifying a used battery available for the secondary use battery among the plurality of used batteries 50. The code information is an example of “identification information”.

After selecting the reference battery, the combination determination apparatus 200 determines whether or not each of the used batteries 50 other than the reference battery is available for the secondary use battery. Hereinafter, a used battery 50 to be determined is referred to as a determination target battery. Among the determination target battery, a battery that is determined to be suitable for use as the secondary use battery is referred to as a combination battery. The combination determination apparatus 200 generates combination information regarding a combination of the used batteries 50.

The combination information includes selection information which is information of the reference battery and availability information which is information of whether or not the determination target battery is available. The combination determination apparatus 200 transmits the generated combination information that includes the selection information and the availability information to the terminal device 100. Hereinafter, configurations of the vehicle 10, the combination determination apparatus 200, and the terminal device 100 are described.

[Vehicle 10]

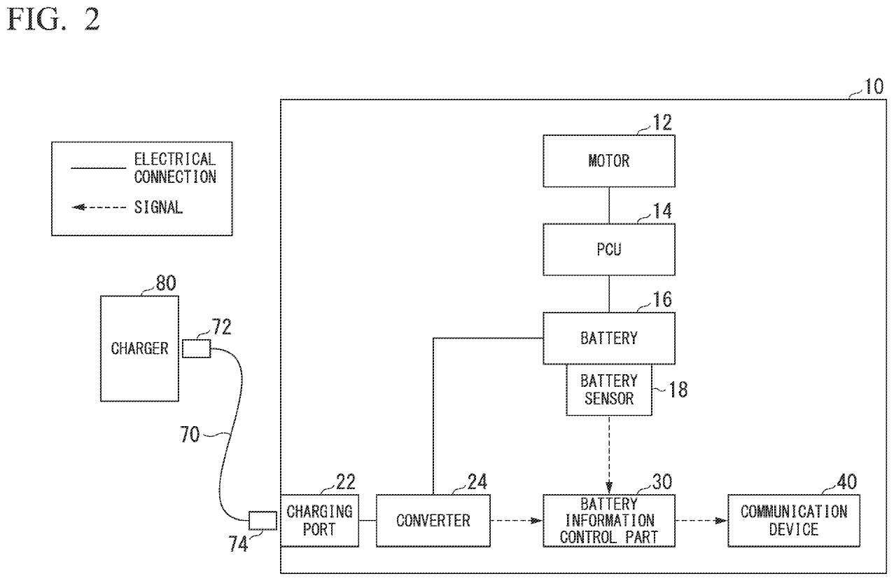

FIG. 2 is a view showing an example of a configuration of the vehicle 10. As shown in FIG. 2, the vehicle 10 includes, for example, a motor 12, a PCU (Power Control Unit) 14, a battery 16, a battery sensor 18, a charging port 22, a converter 24, a battery information control part 30, and a communication device 40.

The motor 12 is, for example, a three-phase AC electric motor. A rotor of the motor 12 is connected to a drive wheel. The motor 12 rotates a drive wheel using supplied electric power. The motor 12 generates electric power using kinetic energy of the vehicle when the vehicle decelerates. The PCU 14 includes, for example, a control part and a DC-DC converter. The control part calculates electric power to be supplied to the motor 12, for example, on the basis of detection values of various sensors provided in the vehicle. For example, the DC-DC converter increases a voltage of electric power supplied from the battery 16 and supplies the electric power calculated by the control part to the motor 12.

The battery 16 is, for example, a secondary battery such as a lithium ion battery. The battery 16 stores electric power introduced from the charger 80 outside the vehicle 10 and performs discharging for traveling of the vehicle 10. The battery sensor 18 is, for example, a group of sensors including an electric current sensor, a voltage sensor, and a temperature sensor. The battery sensor 18 outputs, for example, an electric current value, a voltage value, and a temperature of the battery 16 to the battery information control part 30. The battery 16 becomes a used battery 50 shown in FIG. 1 by being removed from the vehicle 10 after the use of the battery 16 by the vehicle 10 is finished.

The charging port 22 is provided to be directed toward a vehicle body outside of the vehicle 10. The charging port 22 is connected to the charger 80 via the charging cable 70. The charging cable 70 includes a first plug 72 and a second plug 74. The first plug 72 is connected to the charger 80. The second plug 74 is connected to the charging port 22. Electricity supplied from the charger 80 is supplied to the charging port 22 via the charging cable 70. The charger 80 may be connectable to the network NW. The charging cable 70 includes a signal cable attached to an electric power cable. The signal cable mediates communication between the vehicle 10 and the charger 80. Therefore, an electric power connector and a signal connector are provided on each of the first plug 72 and the second plug 74.

The converter 24 is provided between the charging port 22 and the battery 16. The converter 24 converts an electric current introduced from the charger 80 via the charging port 22, for example, an alternating current (AC), into a DC. The converter 24 outputs the converted DC to the battery 16.

The battery information control part 30 calculates a state of the battery 16 on the basis of the electric current value, the voltage value, and the temperature of the battery 16 output by the battery sensor 18. The state of the battery 16 includes, for example, items such as a normal temperature capacity, a low temperature capacity, a normal temperature output, a low temperature output, an efficiency, a self-discharge performance, and a use history. The battery information control part 30 outputs battery information and a battery ID regarding the calculated state of the battery 16 to the communication device 40 when the battery 16 is removed from the vehicle 10.

The communication device 40 includes a radio module for connecting to a cellular network or a Wi-Fi network.

The communication device 40 transmits the battery information output by the battery information control part 30 to the combination determination apparatus 200 via the network NW shown in FIG. 1.

[Terminal Device 100]

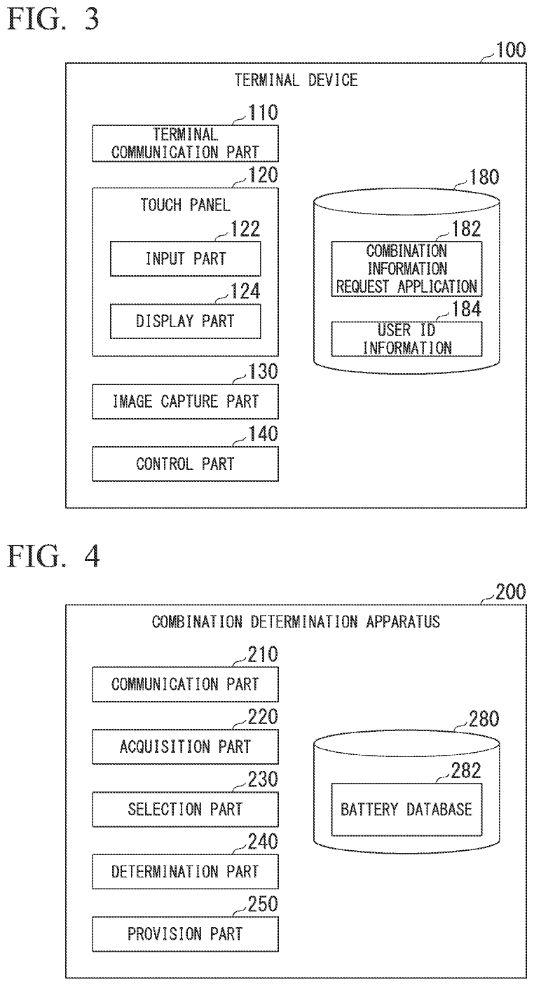

FIG. 3 is a view showing an example of a configuration of the terminal device 100. The terminal device 100 is, for example, a portable terminal device, a tablet, or the like which is used by the user U shown in FIG. 1. The user may be assumed to be, for example, a manufacturer that combines a plurality of used batteries 50 and manufactures a secondary use battery.

As shown in FIG. 3, the terminal device 100 includes, for example, a terminal communication part 110, a touch panel 120, an image capture part 130, a control part 140, and a terminal storage part 180. A combination information request application 182 is installed on the terminal device 100. The terminal storage part 180 stores a combination information request application 182.

The combination information request application 182 is an application program that supports a service including provision of combination information. The terminal device 100 can be used as a device that requires provision of the combination information to the combination determination apparatus 200 by activating the combination information request application 182. The terminal storage part 180 stores user ID information 184 that specifies a user who owns the terminal device 100.

The terminal communication part 110 is, for example, a wireless communication device that can access the network NW using a cellular network or a Wi-Fi network. The terminal communication part 110 transmits request information including a request output by the control part 140 to the combination determination apparatus 200. The request information is information for requesting the combination information. The terminal communication part 110 receives various information transmitted by the combination determination apparatus 200.

The touch panel 120 includes an input part 122 and a display part 124. The input part 122 receives, for example, an input operation based on a manual operation of the user. The input part 122 receives an input operation by the user through a GUI (Graphical User Interface) switch set in the display part 124. The GUI switch is displayed, for example, in a form such as a selection button. The input operation by the user is, for example, an operation in which the user touches (presses) the GUI switch on the touch panel. The input part 122 outputs the input information to the control part 140 when there is an input operation by the user. The display part 124 displays an image based on a control of the control part 140.

The image capture part 130 is, for example, a camera provided to face the outside of a housing of the terminal device 100. For example, the image capture part 130 captures an image of a two-dimensional code 52 assigned to the used battery 50 by a control of the control part 140. The image capture part 130 outputs image information of a captured image to the control part 140.

The two-dimensional code 52 includes code information assigned to the used battery 50. The two-dimensional code 52 may be any code. The two-dimensional code 52 may be, for example, a barcode or a QR code (registered trademark). The code information includes, for example, the battery ID assigned to the used battery 50 and the like.

The two-dimensional code 52 may be displayed directly on the used battery 50, may be displayed on a packing material that packs the used battery 50, or may be displayed in a document, an advertisement, or the like when a transaction for secondary use is performed in a place different from the used battery 50. The two-dimensional code 52 may be displayed through printing or the like or may be displayed in an image or the like using a display device or the like.

The control part 140 receives input information and the like output by the touch panel 120. When the input information has been output by the touch panel 120, the control part 140 causes the touch panel 120 to display a secondary-use-battery use-information input screen. The control part 140 transmits the generated request information to the combination determination apparatus 200 using the terminal communication part 110. The control part 140 acquires a total cost and a use environment of the secondary use battery on the basis of an operation of the secondary-use-battery use-information input screen by the user.

The control part 140 causes the image capture part 130 to capture the two-dimensional code 52 attached to the used battery 50. The control part 140 reads the code information from an image of the two-dimensional code 52 included in the image information output by the image capture part 130. The terminal device 100 reads the two-dimensional code 52 by the image capture part 130 for all of the plurality of used batteries 50 and reads the code information by the control part 140.

The control part 140 generates the request information that includes battery ID information included in the acquired code information of the plurality of used batteries 50, information of the total cost and the use environment of the secondary use battery, and the user ID information 184 stored in the terminal storage part 180. The control part 140 transmits the generated request information to the combination determination apparatus 200 using the terminal communication part 110.

The control part 140 receives combination information transmitted by the combination determination apparatus 200 using the terminal communication part 110. The combination information includes the selection information and the availability information. The control part 140 generates an image in accordance with the received combination information. The control part 140 causes the generated image to be displayed on the display part 124 of the touch panel 120.

[Combination Determination Apparatus 200]

FIG. 4 is a view showing an example of a configuration of the combination determination apparatus 200. As shown in FIG. 2, the combination determination apparatus 200 includes, for example, a communication part 210, an acquisition part 220, a selection part 230, a determination part 240, a provision part 250, and a storage part 280. The acquisition part 220, the selection part 230, the determination part 240, and the provision part 250 are implemented by, for example, a hardware processor such as a CPU (Central Processing Unit) executing a program (software). Some or all of these components may be implemented by hardware (a circuit part including circuitry) such as an LSI (Large Scale Integration), an ASIC (Application Specific Integrated Circuit), a FPGA (Field-Programmable Gate Array), or a GPU (Graphics Processing Unit) or may be implemented by software and hardware in cooperation. The program may be stored in a storage device (a non-transitory storage medium) such as a HDD (Hard Disk Drive) in advance or a flash memory or may be stored in a removable storage medium (a non-transitory storage medium) such as a DVD or a CD-ROM and installed when the storage medium is mounted in a drive device. The storage part 280 is implemented by the storage device described above.

The communication part 210 includes a communication interface such as a NIC. The communication part 210 performs communication between the communication device 40 mounted on the vehicle 10 and the terminal communication part 110 mounted on the terminal device 100 via the network NW. The communication part 210 receives the battery information transmitted by each of a plurality of vehicles 10 and the request information transmitted by the terminal device 100. The communication part 210 outputs the received battery information and the received request information to the acquisition part 220.

The acquisition part 220 acquires the battery information output by the communication part 210. When the battery information is acquired, the acquisition part 220 adds new battery information to a battery database 282 stored in the storage part 280 and updates the battery database 282.

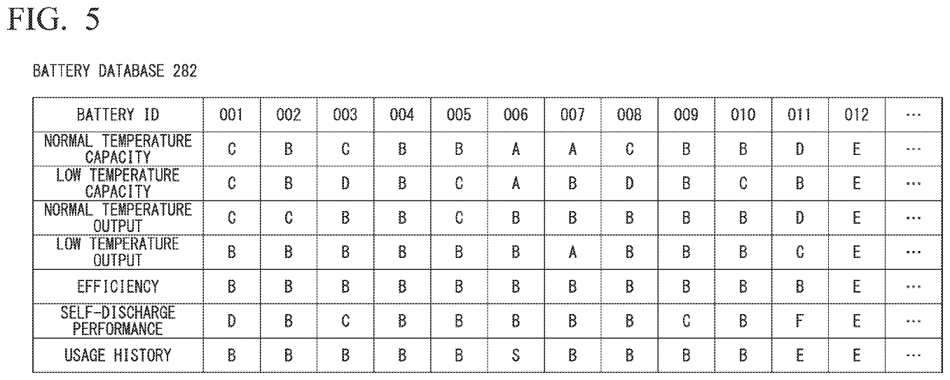

Here, the battery database 282 is described. FIG. 5 is a view showing an example of the battery database 282. As shown in FIG. 5, the battery database 282 includes battery IDs assigned to the plurality of batteries 16, respectively. The battery database 282 includes items of a “normal temperature capacity”, a “low temperature capacity”, a “normal temperature output”, a “low temperature output”, an “efficiency”, a “self-discharge performance,” and a “usage history” as elements in each of the plurality of batteries 16. In the battery database 282, evaluation ranks of the items of the “normal temperature capacity”, the “low temperature capacity”, the “normal temperature output”, the “low temperature output”, the “efficiency”, the “self-discharge performance”, and the “usage history” with respect to the plurality of batteries 16 are stored. The evaluation ranks are “S”, “A”, “B”, “C”, “D”, “E”, and “F” in a descending order. For example, in a battery having a battery ID of “001”, the “normal temperature capacity” is “C”, the “low temperature capacity” is “C”, the “normal temperature output” is “C”, the “low temperature output” is “B”, the “efficiency” is “B”, the “self-discharge performance” is “D”, and the “usage history” is “B”.

The acquisition part 220 receives the request information output by the communication part 210. When receiving the request information, the acquisition part 220 authenticates the user transmitting the request information on the basis of the user ID information included in the request information. The acquisition part 220 may perform user authentication in another way. For example, the acquisition part 220 may authenticate the user by biometric authentication such as user's face authentication instead of or in addition to the authentication by the user ID.

The selection part 230 reads battery information indicating a battery state of the used battery 50 having the battery ID included in the request information from the battery database 282. The selection part 230 selects a reference battery from the used batteries 50 on the basis of a battery state of each of the used batteries 50 shown in the read battery information. When selecting the reference battery, the selection part 230 compares, for example, variations of the items of the battery state in the plurality of used batteries 50. The selection part 230 selects, for example, a used battery 50 having the lowest variation of the items as the reference battery. The reference battery may be selected in another way. For example, the reference battery may be selected based on the total cost and the use environment of the secondary use battery instead of or in addition to the variation of the battery information of the used battery 50.

For example, it is assumed that the battery IDs included in the request information transmitted by the terminal device 100 are “002”, “004”, “005”, “008”, and “010”. In this case, among the battery database 282 shown in FIG. 4, the used battery 50 having a battery ID of “004” represents an evaluation rank of “B” for all items and has the smallest variation. Therefore, the selection part 230 selects the used battery 50 having the battery ID of “004” as the reference battery.

The determination part 240 specifies a used battery 50 that becomes a determination target battery on the basis of the battery ID transmitted by the terminal device 100. Among the plurality of used batteries 50 that store battery information in the battery database 282, the determination part 240 determines that used batteries 50 other than the reference battery among the used batteries 50 including the battery ID transmitted by the terminal device 100 are the determination target battery.

The determination part 240 determines whether or not a determination target battery is available as the combination battery when the secondary use battery is manufactured. Therefore, the determination part 240 compares a battery state of each of the used batteries 50 other than the reference battery with a battery state of the reference battery. The determination part 240 determines whether or not the determination target battery is available as the combination battery on the basis of a result of comparison between the battery state of the determination target battery and the battery state of the reference battery. Whether or not the determination target battery is available as the combination battery may be determined only by comparing the battery state of the determination target battery with the battery state of the reference battery, or may be determined by referring to a comparison result between a battery state of another determination target battery and the battery state of the reference battery. The availability referred to in the embodiment does not indicate whether or not a battery is available for secondary use but indicates whether or not a battery is available in combination with the reference battery.

When determining whether or not the determination target battery is available as the combination battery only by comparing the battery state of the determination target battery with the battery state of the reference battery, for example, the determination target battery may be determined to be available in a case where the number of items representing a different evaluation rank is equal to or less than two as a result of comparison between the battery state of the determination target battery and the battery state of the reference battery, and the determination target battery may be determined to be unavailable in a case where the number of items representing a different evaluation rank is three or more. Further, in the item of evaluation, the determination target battery may be determined to be available in a case where the rank of the determination target battery is separated by equal to or less than one rank from the rank of the reference battery, and the determination target battery may be determined to be unavailable in a case where the rank of the determination target battery is separated by equal to more than two ranks from the rank of the reference battery. Further, the availability as the combination battery may be determined by considering together the number of items representing a different evaluation rank and the separation degree of the rank in the item representing a different evaluation rank.

For example, the determination part 240 may adjust or set a reference of determination whether or not the determination target battery is available as the combination battery on the basis of the use environment and the total cost. For example, in a case where the use environment of the secondary use battery is a warm location, the difference in a low temperature capacity from the reference battery for determining that the determination target battery is suitable for the combination battery may be larger than that in a case where the use environment is a low temperature location. Further, in a case where the total cost is high, when there is an item having a higher evaluation rank than the evaluation rank of the reference battery, it may be determined that the determination target battery is not suitable for the combination battery. In a case where the total cost is low, even when there is an item having a higher evaluation rank than the evaluation rank of the reference battery, it may be determined that the determination target battery is suitable for the combination battery.

In a case where the availability as the combination battery is determined with reference to a comparison result between the battery states of other determination target batteries and the battery state of the reference battery, for example, the number of items in which the battery state of the determination target battery is different from the battery state of the reference battery may be compared for a plurality of determination target batteries, and it may be determined that determination target batteries having a small number of items are available and other used batteries are unavailable. Further, in place of or in addition to the number of different items, the availability as the combination battery may be determined with reference to the degree of separation of the rank in an item having a different evaluation rank. Further, the number of the determination target batteries that are available may be determined in advance, or it may be possible to determine the availability as the combination battery at the time of determination.

The provision part 250 generates combination information that includes selection information identifying the reference battery selected by the selection part 230 and availability information indicating whether or not the determination target battery is available as the combination battery. The provision part 250 transmits and provides the generated combination information to the terminal device 100 using the communication part 210. The provision part 250 causes the communication part 210 to transmit the determination result by the determination part 240. The provision part 250 is an example of a “transmission control part”.

Next, processes of the vehicle 10, the terminal device 100, and the combination determination apparatus 200 will be individually described with respect to a process executed in the combination determination system 1.

[Process of Vehicle 10]

The vehicle 10 calculates the state of the battery 16 mounted on the vehicle 10 at an appropriate timing in the battery information control part 30. The appropriate timing may be specified in any manner and may be, for example, a timing with a regular time interval or a predetermined time. The vehicle 10 stores the battery information calculated in the battery information control part 30. When the battery 16 is removed from the vehicle 10, the vehicle 10 transmits the stored battery information to the combination determination apparatus 200 by the communication device 40.

[Process of Terminal Device 100]

The terminal device 100 transmits request information to the combination determination apparatus 200 in response to an operation of a user of the terminal device 100, receives the combination determination information provided by the combination determination apparatus 200, and displays the combination determination information on the display part 124 of the touch panel 120. Hereinafter, for example, a procedure until a user who has a battery for which combination information is desired to be received transmits the request information, and a procedure until the combination information is received and displayed on the display part 124 of the touch panel 120 are described.

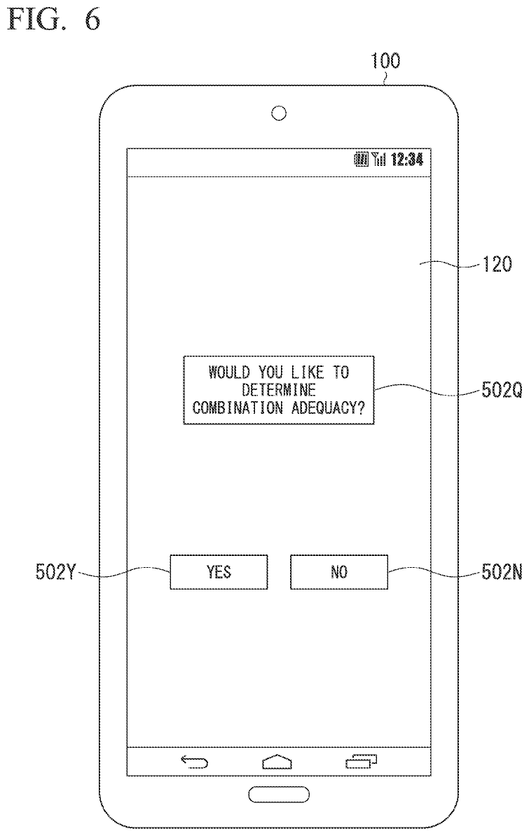

The user who wants to receive the combination information operates the terminal device 100 so as to start up the combination information request application 182. The terminal device 100 that has received the operation activates the combination information request application 182 through the control part 140. FIG. 6 is a view showing an example of an image displayed on the terminal device 100 in which the combination information request application 182 is activated.

As shown in FIG. 6, the control part 140 causes the touch panel 120 to display a request image 502Q, an agreement button 502Y, and a reject button 502N. The request image 502Q is an image that displays “Would you like to determine the combination adequacy of a battery?” and is an image which notifies the user that the combination information can be requested.

The agreement button 502Y is a GUI switch that displays “Yes”. When the user wants to request the combination information, the user operates the agreement button 502Y. The reject button 502N is a GUI switch that displays a text of “No”. A user who does not intend to request combination information and wants to end the combination information request application 182 operates the reject button 502N.

When the user operates the agreement button 502Y or the rejection button 502N as an input operation, the touch panel 120 outputs the input information to the control part 140. The control part 140 to which input information based on the operation of the agreement button 502Y is output causes the touch panel 120 to display the secondary-use-battery use-information input screen. The control part 140 to which input information based on the operation of the rejection button 502N terminates the combination information request application 182.

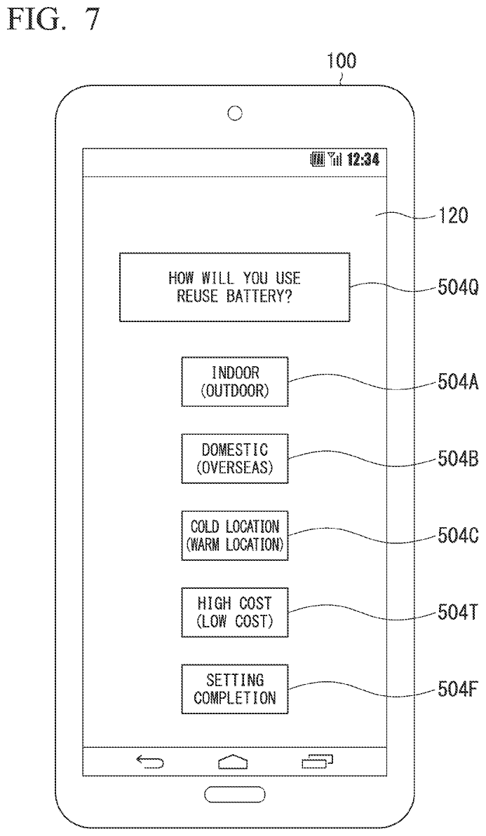

FIG. 7 is a view showing an example of an image displayed on the terminal device 100 in which the agreement button 502Y is operated. The screen shown in FIG. 7 is the secondary-use-battery use-information input screen. The secondary-use-battery use-information input screen displayed on the display part 124 of the touch panel 120 by the control part 140 includes an inquiry image 504Q, a first use environment button 504A, a second use environment button 504B, a third use environment button 504C, a total cost button 504T, and a setting completion button 504F as shown in FIG. 7.

The inquiry image 504Q is an image that displays “How will you use the reuse battery?” and is an image which notifies the user that the use environment of the secondary use battery and the total cost are inquired. The first use environment button 504A is a GUI switch that displays a text of “Indoor” or “Outdoor”. Each time the user operates the first use environment button 504A, the text displayed on the first use environment button 504A is switched between “Indoor” or “Outdoor”.

The second use environment button 504B is a GUI switch that displays a text of “Domestic” or “Overseas”. Each time the user operates the second use environment button 504B, the text displayed on the second use environment button 504B is switched between “Domestic” or “Overseas”. The third use environment button 504C is a GUI switch that displays a text of “Cold location” or “Warm location”. Each time the user operates the third use environment button 504C, the text displayed on the third use environment button 504C is switched between “Cold location” or “Warm location”.

The total cost button 504T is a GUI switch that displays a text of “High cost” or “Low cost”. Each time the user operates the total cost button 504T, the text displayed on the total cost button 504T is switched between “High cost” or “Low cost”. For example, the user U selects “high cost” in a case where it is desired to enhance the performance of the secondary use battery even if the total cost is high. The user U selects “low cost” in a case where it is desired to reduce the total cost even if the performance of the secondary use battery is low.

The setting completion button 504F is a GUI switch that displays a text of “Setting completion”.

The user operates the setting completion button 504F, and thereby, the control part 140 sets the total cost and the use environment of the secondary use battery that are consistent with the displays of the first use environment button 504A, the second use environment button 504B, the third use environment button 504C, and the total cost button 504T.

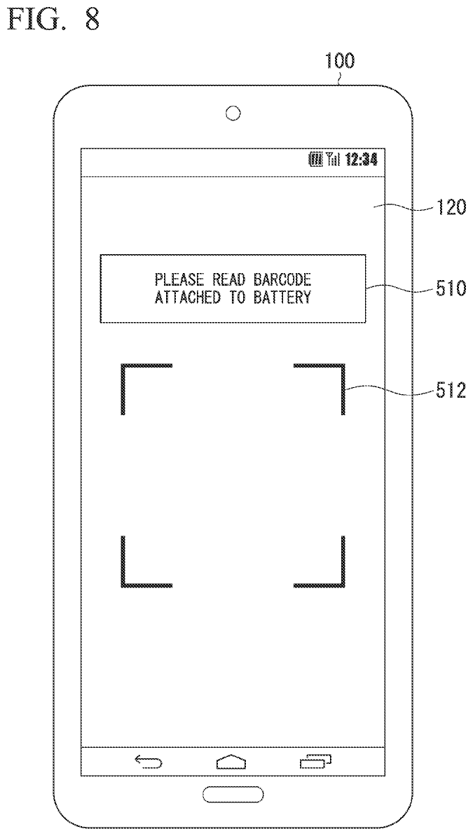

FIG. 8 is a view showing an example of an image displayed on the terminal device 100 after setting the total cost and the use environment of the secondary use battery. As shown in FIG. 8, the control part 140 causes the touch panel 120 to display a photography instruction image 510 and a frame image 512 after setting the total cost and the use environment of the secondary use battery. For example, the control part 140 causes a text image of “Please read the barcode attached to the battery” to be displayed as the photography instruction image 510. The control part 140 causes the frame image 512 to be displayed below the photography instruction image 510. In this way, the terminal device 100 causes the user U to perform a reading work of the two-dimensional code 52.

For example, when the user U performs an operation by which the image capture part 130 reads the two-dimensional code 52 included in the frame image 512 in accordance with the instruction based on the photography instruction image 510, the control part 140 causes the image capture part 130 to photograph the two-dimensional code 52. The image capture part 130 outputs image information including the two-dimensional code 52 to the control part 140.

The control part 140 reads code information from the image of the two-dimensional code 52 included in the image information output by the image capture part 130 and acquires battery ID information included in the code information.

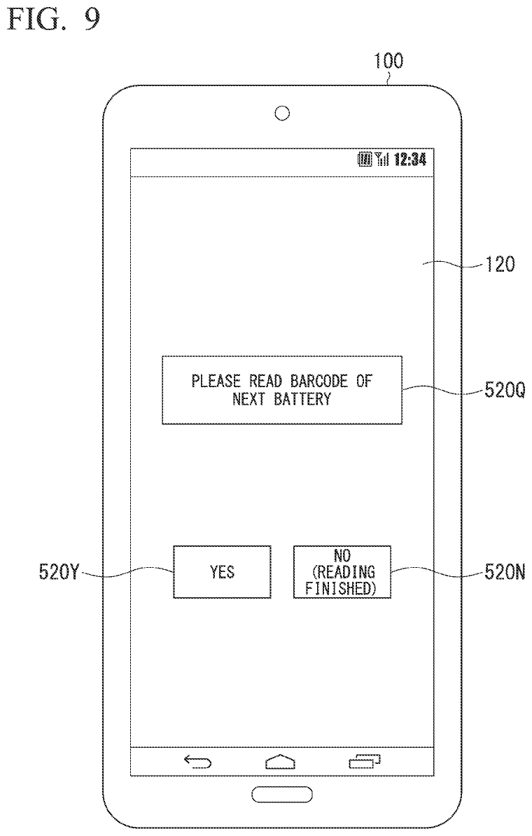

Subsequently, the control part 140 causes a screen shown in FIG. 9 to be displayed on the touch panel 120, assuming that there may be a used battery 50 of which the two-dimensional code 52 is not read.

FIG. 9 is a view showing an example of an image displayed on the terminal device 100 after the two-dimensional code 52 is read by the image capture part 130. The control part 140 causes the touch panel 120 to display a reading prompt image 520Q, a reading performing button 520Y, and a reading finish button 520N, as shown in FIG. 9. The reading prompt image 520Q is an image that displays “Please read the bar code of the next battery” and is an image that prompts the user U to read the two-dimensional code 52 in another used battery 50 of which the two-dimensional code 52 is not read.

The reading performing button 520Y is a GUI switch that displays “Yes”.

In a case where there is a used battery 50 of which the reading of the two-dimensional code 52 is not completed, the user U operates the reading performing button 520Y. The reading finish button 520N is a GUI switch that displays a text of “No (reading finished)”. After reading the two-dimensional codes 52 of all of the used batteries 50, the user U operates the rejection button 502N and finishes the reading work of the two-dimensional code.

After the user U finishes the reading work of the two-dimensional code, the control part 140 reads out the user ID information 184 stored in the terminal storage part 180. The control part 140 generates request information on the basis of battery ID information, information of the use environment and the total cost, and the user ID information 184. The control part 140 transmits the generated request information to the combination determination apparatus 200 using the terminal communication part 110.

Further, in a case where the combination information is transmitted by the combination determination apparatus 200 when the combination information request application 182 is activated, the terminal device 100 receives the transmitted combination information through the terminal communication part 110. In a case where the terminal device 100 receives the combination information when the combination information request application 182 is not activated, the combination information request application 182 may be activated.

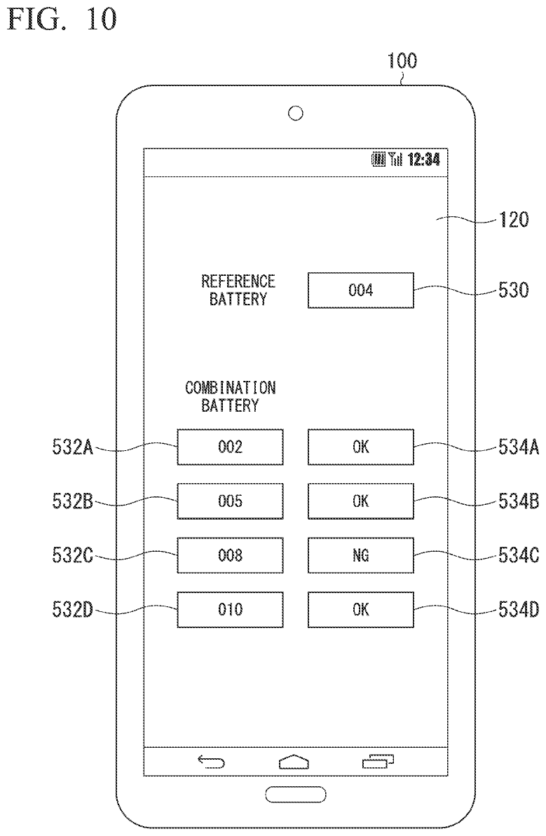

The terminal communication part 110 outputs the received combination information to the control part 140. In a case where the combination information output by the terminal communication part 110 is acquired, the control part 140 causes the display part 124 of the touch panel 120 to display an image corresponding to the selection information and the availability information included in the combination information. FIG. 10 is a view showing an example of an image displayed on the terminal device 100 that receives the combination information.

As shown in FIG. 10, the touch panel 120 of the terminal device 100 that receives the combination information displays a reference battery ID screen 530, a first combination battery ID screen 532A to a fourth combination battery ID screen 532D, and a first combination battery use availability screen 534A to a fourth combination battery use availability screen 534D. The reference battery ID screen 530 is a screen showing a battery ID of the used battery 50 that becomes the reference battery. The first combination battery ID screen 532A to the fourth combination battery ID screen 532D are screens showing battery IDs of a first used battery to a fourth used battery indicating availability information. The first combination battery use availability screen 534A to the fourth combination battery use availability screen 534D are screens showing whether or not the first used battery to the fourth used battery are available as the combination battery.

In the example shown in FIG. 10, the used battery 50 of the battery ID of “004” becomes the reference battery. The used batteries 50 of the battery IDs of “002”, “005”, and “010” are a battery that is suitable as the combination battery, and the used battery 50 of the battery ID of “008” is a battery that is not suitable as the combination battery. In this way, the terminal device 100 displays the reference battery and whether or not the used batteries 50 other than the reference battery are available as the combination battery.

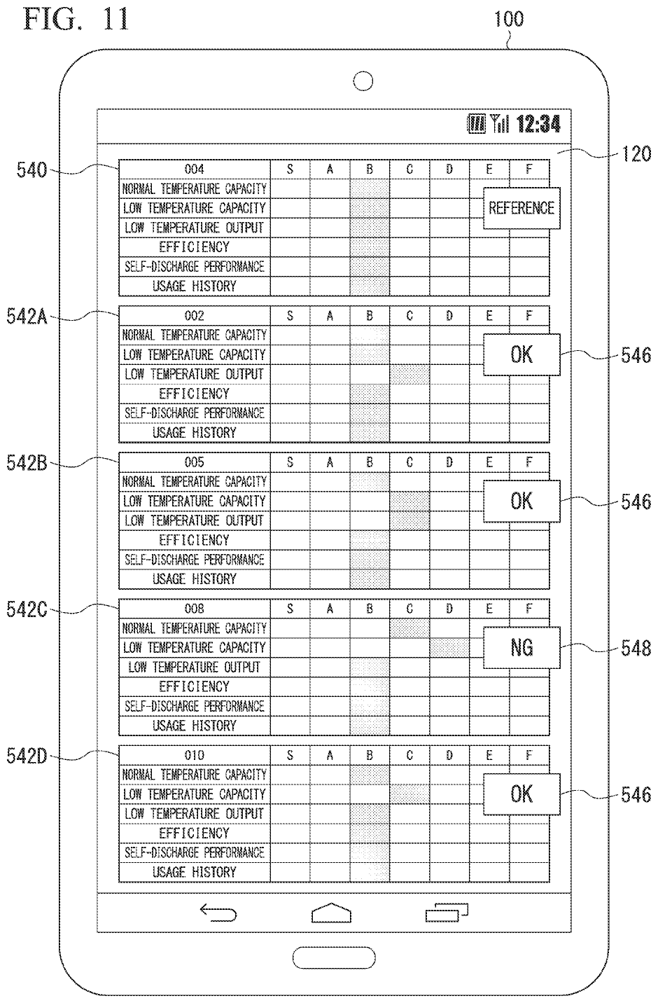

As the display of the reference battery and the combination battery, for example, an evaluation rank capable of being evaluated such as “S” to “F”, and an evaluation rank obtained by evaluating each used battery 50 may be displayed. FIG. 11 is a view showing another example of an image displayed on the terminal device 100 that receives the combination information. As shown in FIG. 11, for example, in the used battery 50 having a battery ID of “004”, the evaluation of “B” among the evaluation ranks of “S” to “F” is colored and marked for all of the items. Therefore, it can be known that the used battery 50 having the battery ID of “004” is evaluated that the evaluation ranks of all of the items are “B”.

Further, in the display shown in FIG. 11, a text indicated as “Reference” is displayed on the evaluation display 540 of a used battery 50 that becomes the reference battery among the used batteries 50, which is here a used battery 50 having a battery ID of “004”. This display indicates that the used battery 50 having a battery ID of “004” is the reference battery. Further, among the evaluation displays of the used batteries 50, a qualification label image 546 indicating “OK” is displayed on the evaluation displays 542A, 542B, and 542D of the used batteries 50 which are available as the combination battery, which are here the evaluation displays having the battery IDs of “002”, “005”, and “010”. Further, among the evaluation displays of the used batteries 50, a non-qualification label image 548 indicating “NG” is displayed on the evaluation display of the used battery 50 which is unavailable as the combination battery, which is here the evaluation display 542C having the battery ID of “008”.

[Process of Combination Determination Apparatus 200]

Subsequently, a process of the combination determination apparatus 200 is described. The combination determination apparatus 200 mainly performs a process of updating the battery database 282 and a process of providing combination information. These processes may be performed in a series of processes or may be performed in different processes. In the embodiment, the process of updating the battery database 282 and the process of providing the combination information is described as different processes.

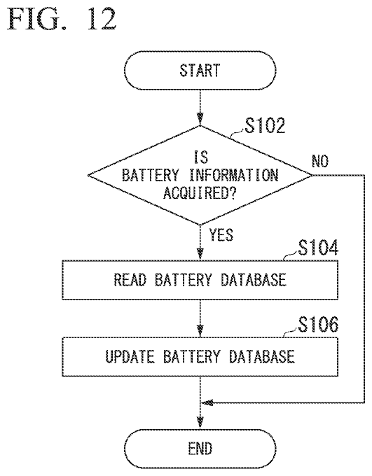

First, the process of updating the battery database 282 is described. FIG. 12 is a flowchart showing an example of the process of the combination determination apparatus 200. As shown in FIG. 12, the combination determination apparatus 200 determines whether or not the acquisition part 220 has acquired the battery information transmitted by the vehicle 10 (Step S102). When it is determined that the acquisition part 220 has not acquired the battery information, the combination determination apparatus 200 ends the process shown in FIG. 12. When it is determined that the acquisition part 220 has acquired the battery information, the acquisition part 220 reads the battery database 282 stored in the storage part 280 (Step S104). Subsequently, the acquisition part 220 adds the acquired battery information to the battery database 282 and updates the battery database 282 (Step S106). In this way, the combination determination apparatus 200 updates the battery database 282 and ends the process shown in FIG. 12.

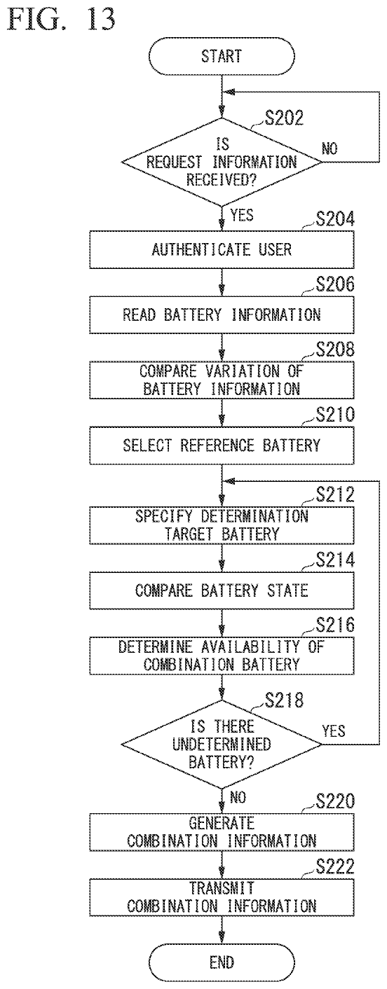

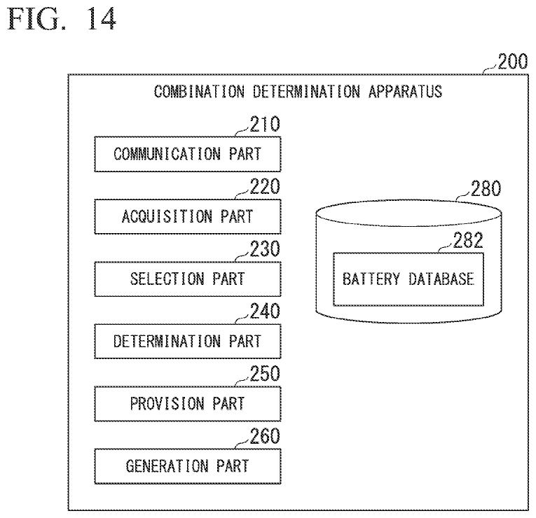

Subsequently, the process of providing the combination information is described. FIG. 13 is a flowchart showing another example of the process of the combination determination apparatus 200. As shown in FIG. 13, the combination determination apparatus 200 determines whether or not the acquisition part 220 has received request information transmitted by the terminal device 100 (Step S202). When it is determined that the request information transmitted by the terminal device 100 has not been received, the combination determination apparatus 200 repeats the process of Step S202.

When it is determined that the request information transmitted by the terminal device 100 has been received, the acquisition part 220 performs authentication of the user U on the basis of the user ID included in the request information (Step S204). The selection part 230 reads battery information corresponding to the battery ID included in the request information from the battery database 282 after the acquisition part 220 performs authentication of the user U (Step S206).

Subsequently, the selection part 230 compares variations of the items of the battery state indicated in the read battery information (Step S208). The selection part 230 selects, as the reference battery, a used battery 50 having the smallest variation of the items of the battery state from the plurality of used batteries 50 (Step S210).

When the selection part 230 selects the reference battery, the determination part 240 specifies a determination target battery from the used batteries 50 other than the reference battery (Step S212). The determination target battery is arbitrarily specified from used batteries 50 that have not been a determination target battery among the used batteries 50 having a battery ID included in the request information.

After specifying the determination target battery, the determination part 240 compares the battery state of the determination target battery with the battery state of the reference battery (Step S214). Subsequently, the determination part 240 determines whether or not the determination target battery is available as the combination battery on the basis of a comparison result between the battery state of the determination target battery and the battery state of the reference battery (Step S216).

Subsequently, the determination part 240 determines whether or not a used battery 50 that has not been the determination target battery remains among the used batteries 50 having the battery ID included in the request information (Step S218). When it is determined that a used battery 50 that has not been the determination target battery remains, the determination part 240 returns to Step S212, specifies the determination target battery, and proceeds to Step S214.

When it is determined that a used battery 50 that has not been the determination target battery does not remain, the provision part 250 generates combination information that includes the selection information and the availability information (Step S220). Then, the provision part 250 transmits the generated combination information to the terminal device 100 using the communication part 210 (Step S222). In this way, the combination determination apparatus 200 ends the process shown in FIG. 13.

According to the first embodiment described above, the combination determination apparatus 200 selects a reference battery when manufacturing a secondary use battery from a plurality of used batteries 50 on the basis of the battery state of each of the used batteries. Further, the combination determination apparatus 200 specifies a determination target battery from the used batteries 50 other than the reference battery on the basis of the request information transmitted by the terminal device 100 and determines whether or not the determination target battery is available as a combination battery on the basis of the battery state of the determination target battery. Therefore, it is possible to suitably select a used battery that is used when manufacturing the secondary use battery.

Further, the combination determination apparatus 200 selects the reference battery on the basis of the variation of the battery state of the used battery. Therefore, it is possible to make it easier to determine the availability of the used batteries 50 other than the reference battery. Further, the combination determination apparatus 200 generates the combination information on the basis of the request information transmitted by the terminal device 100 and transmits the combination information to the terminal device transmitting the request information. Therefore, the combination determination apparatus 200 is able to provide combination information to a user U who requires the combination information.

In the first embodiment, the user U receives the combination information by reading the two-dimensional code 52 of all of the used batteries 50 but may receive the combination information in another way. For example, the user U may read the two-dimensional code 52 of all of the used batteries 50, and the combination determination apparatus 200 may first select a reference battery. In this case, subsequently, each time the user U reads the two-dimensional code of the used battery 50, the terminal device 100 may transmit the code information to the combination determination apparatus 200, and the combination determination apparatus 200 may determine whether or not the used battery 50 having a battery ID indicated by the transmitted code information is suitable as the combination battery and may transmit the combination information to terminal device 100. In this way, the user U can know whether or not the used battery having the two-dimensional code 52 is available as the combination battery each time the two-dimensional code 52 is read.

Further, the combination determination apparatus 200 may propose the reference battery to the user U, and the user U may accept the proposal. In this case, the user U accepts the reference battery and then reads the two-dimensional code 52 attached to the used battery 50 other than the reference battery, and thereby, the combination information of the used battery 50 of which the two-dimensional code 52 is read by the combination determination apparatus 200 may be transmitted to the terminal device 100. The combination determination apparatus 200 may perform the selection of the reference battery, for example, on the basis of only the variation of the items in the battery information of the used battery. In a case where the proposal of the combination determination apparatus 200 is rejected by the user U, the combination determination apparatus 200 may propose another used battery 50 as the reference battery.

### Second Embodiment

A second embodiment of the combination determination apparatus is described. In the description of the second embodiment, elements common to those of the first embodiment may be given the same reference numerals, and the description thereof may be omitted.

FIG. 14 is a view showing an example of a configuration of a combination determination apparatus 200 according to the second embodiment. As shown in FIG. 14, the combination determination apparatus 200 of the second embodiment includes a communication part 210, an acquisition part 220, a selection part 230, a determination part 240, a provision part 250, a generation part 260, and a storage part 280. The generation part 260 generates a plurality of combinations of the used batteries 50 including a reference battery and a combination battery from the used batteries 50 included in the battery database 282 on the basis of the selection result of the selection part 230 and the determination result of the determination part 240.

The generation part 260 transmits the selection information regarding the plurality of generated combinations of the used batteries 50 to another device which is, for example, the terminal device 100 by using the communication part 210. For example, in a case where a display device is provided on the apparatus that includes the generation part 260, the generation part 260 may not transmit the selection information to another device and may display an image corresponding to the selection information on the display device or the like.

The selection part 230 selects a reference battery, for example, on the basis of the battery state of the used battery 50 stored in the battery database 282. Subsequently, the determination part 240 compares the battery state of the used battery 50 other than the reference battery with the battery state of the reference battery and determines the availability as a used battery. The generation part 260 generates a combination pattern of the reference battery selected by the selection part 230 and the used batteries 50 that are determined as a combination battery by the determination part 240. The provision part 250 transmits and provides a combination of the used batteries 50 as a generation result generated by the generation part 260 to the terminal device 100.

For example, in a case where a condition is imposed in selecting the reference battery, the selection part 230 selects the reference battery in consideration of the imposed condition on the basis of the battery state of all of the used batteries 50 stored in the battery database 282. Similarly, in a case where a condition is imposed in determining the combination battery, the determination part 240 selects the reference battery in consideration of the imposed condition on the basis of the battery state of the used batteries 50 excluding the reference battery among all of the used batteries 50 stored in the battery database 282. The condition here may be, for example, a condition regarding the secondary use battery such as the use environment of the secondary use battery, the total cost, the number of used batteries that are used for the secondary use battery. Alternatively, the condition may be a physical condition such as an individual item of the battery state or the size of the used battery 50 or the like.

The selection part 230 may select a reference battery under different conditions, and the determination part 240 may determine the combination battery under different conditions, generate a combination pattern of the used batteries 50, and propose a combination pattern of the used batteries generated under the respective different conditions. A combination pattern may be generated by selecting a reference battery and a combination battery, for example, according to a pattern (hereinafter, referred to as a “normal pattern”) that does not impose a condition on the selection of the reference battery and the determination of the combination battery, a pattern that presents the lowest price (hereinafter, referred to as a “low-price pattern”), a pattern that presents the highest performance (hereinafter, referred to as a “high-spec pattern”), or a pattern that presents the smallest size (hereinafter, referred to as a “space-saving pattern”).

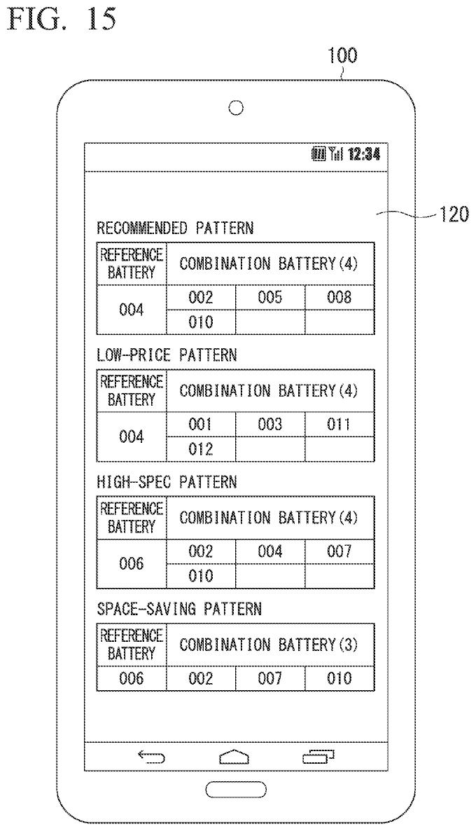

In this case, for example, the used battery 50 is selected as a reference battery and a combination battery according to the normal pattern, the low-price pattern, the high-spec pattern, and the space-saving pattern, and the combination information is transmitted to the terminal device 100. The terminal device 100 causes the touch panel 120 to display the battery ID of the used battery 50 in each of the normal pattern, the low-price pattern, the high-spec pattern, and the space-saving pattern as shown in FIG. 15.

According to the second embodiment described above, it is possible to provide the combination information to a user U who does not hold the used battery 50 and is not able to read the two-dimensional code. Accordingly, it is possible to provide the combination information to a user having less information regarding the used battery 50.

Although embodiments of the present invention have been described, the present invention is not limited to such embodiments, various modifications and substitutions can be made without departing from the scope of the present invention.

What is claimed is:

1. A combination determination apparatus comprising:
a selection part that selects, from a plurality of secondary batteries having a use history, a reference battery when part or all of the plurality of secondary batteries are combined to be a secondary use battery, based on a state of each of the plurality of secondary batteries; and
a determination part that determines an availability of each of secondary batteries other than the reference battery among the plurality of secondary batteries as a combination battery that are combined with the reference battery to be the secondary use battery, based on a state of each of the secondary batteries other than the reference battery.

2. The combination determination apparatus according to claim 1,
wherein the determination part determines the availability of each of the secondary batteries other than the reference battery among the plurality of secondary batteries, based on a use environment of the secondary use battery.

3. The combination determination apparatus according to claim 1,
wherein the determination part determines the availability of each of the secondary batteries other than the reference battery among the plurality of secondary batteries, based on a total cost of the secondary use battery.

4. The combination determination apparatus according to claim 1,
wherein the selection part selects the reference battery based on a variation in a condition of the secondary battery.

5. The combination determination apparatus according to claim 1, further comprising:
a communication part that communicates with a terminal device;
an acquisition part that acquires a state of a secondary battery that corresponds to identification information of the secondary battery that is transmitted by the terminal device; and
a transmission control part that causes the communication part to transmit a determination result by the determination part,
wherein the determination part specifies a secondary battery of which an availability is determined based on the identification information of the secondary battery that is transmitted by the terminal device, and
the transmission control part causes the communication part to transmit the determination result by the determination part to the terminal device that has transmitted the identification information.

6. The combination determination apparatus according to claim 1, further comprising:
a generation part that generates a combination pattern of the secondary batteries to be the secondary use battery based on a selection result of the selection part and a determination result of the determination part; and
a provision part that provides a generation result of the generation part,
wherein the generation part generates a plurality of combinations of the secondary batteries to be the secondary use battery, and
the provision part provides a plurality of combinations of the secondary batteries.

7. A combination determination method by a computer, comprising:
selecting, from a plurality of secondary batteries having a use history, a reference battery when part or all of the plurality of secondary batteries are combined to be a secondary use battery, based on a state of each of the plurality of secondary batteries; and
determining an availability of each of secondary batteries other than the reference battery among the plurality of secondary batteries as a combination battery that are combined with the reference battery to be the secondary use battery, based on a state of each of the secondary batteries other than the reference battery.

8. A computer-readable non-transitory recording medium that includes a program causing a computer to:
select, from a plurality of secondary batteries having a use history, a reference battery when part or all of the plurality of secondary batteries are combined to be a secondary use battery, based on a state of each of the plurality of secondary batteries; and
determine an availability of each of secondary batteries other than the reference battery among the plurality of secondary batteries as a combination battery that are combined with the reference battery to be the secondary use battery, based on a state of each of the secondary batteries other than the reference battery.
